(19) United States
(12) Patent Application Publication
(10) Pub. No.: US 2011/0140071 A1
(43) Pub. Date: Jun. 16, 2011

(54) NANO-SPHERICAL GROUP III-NITRIDE MATERIALS

(76) Inventors: Olga Kryliouk, Sunnyvale, CA (US); Yuriy Melnik, Santa Clara, CA (US); Hidehiro Kojiri, Sunnyvale, CA (US); Tetsuya Ishikawa, Saratoga, CA (US)

(21) Appl. No.: 12/967,970

(22) Filed: Dec. 14, 2010

Related U.S. Application Data
(60) Provisional application No. 61/286,310, filed on Dec. 14, 2009.

(51) Int. Cl. H01L 33/04; B82Y 99/00

(52) U.S. Cl. 257/9; 438/46; 257/13; 257/E33.023; 977/762

(57) ABSTRACT

Nano-spherical group III-nitride materials and methods of forming nano-spherical group III-nitride materials are described. Also described is a 1-dimensional LED or similar device formed from a single nano-rod of a nano-spherical group III-nitride material.

### CROSS-REFERENCE TO RELATED APPLICATIONS

This application claims the benefit of U.S. Provisional Application No. 61/286,310, filed Dec. 14, 2009, the entire contents of which are hereby incorporated by reference herein.

### BACKGROUND

1) Field

Embodiments of the present invention pertain to the field of hydride vapor phase epitaxy and, in particular, to nano-spherical group III-nitride materials and methods of forming nano-spherical group III-nitride materials.

2) Description of Related Art

Group III-V materials are playing an ever increasing role in the semiconductor and related, e.g. light-emitting diode (LED), industries. Often, group III-nitride materials are used because of their particularly useful optoelectronic characteristics.

### BRIEF DESCRIPTION OF THE DRAWINGS

FIG. 1A is a scanning electron microscope image of an angled top-down view of a pair of nano-spherical group III-nitride material structures, in accordance with an embodiment of the present invention.

FIG. 1B is a scanning electron microscope image blown-up view of one of the pair of nano-spherical group III-nitride material structures from FIG. 1A, in accordance with an embodiment of the present invention.

FIG. 2A is a cross-sectional tunneling electron microscope (TEM) image of a nano-spherical group III-nitride material structure, in accordance with an embodiment of the present invention.

FIG. 2B is a tunneling electron microscope (TEM) image blown-up view of the nano-spherical group III-nitride material structure from FIG. 2A, in accordance with an embodiment of the present invention.

FIG. 3 illustrates a compositional plot of the atomic composition of a nano-spherical group III-nitride material structure, in accordance with an embodiment of the present invention.

FIG. 4 is a high angle annular dark field TEM image of a cross-sectional view of a nano-spherical group III-nitride material structure, in accordance with an embodiment of the present invention.

FIG. 5A illustrates a cross-section of a representative portion of an LED device, in accordance with an embodiment of the present invention.

FIG. 5B illustrates a cross-section of a representative portion of an LED device, in accordance with an embodiment of the present invention.

FIG. 6 is a schematic view of an HVPE apparatus, in accordance with an embodiment of the present invention.

FIG. 7A illustrates a transparent, isometric view of a representative portion of an LED device, in accordance with an embodiment of the present invention.

FIG. 7B illustrates a top-down view of a representative portion of an LED device, in accordance with an embodiment of the present invention.

FIG. 8 is a schematic cross-sectional view of an MOCVD chamber, in accordance with an embodiment of the present invention.

### DETAILED DESCRIPTION

Nano-spherical group III-nitride materials and methods of forming nano-spherical group III-nitride materials are described. In the following description, numerous specific details are set forth, such as fabrication conditions and material regimes, in order to provide a thorough understanding of embodiments of the present invention. It will be apparent to one skilled in the art that embodiments of the present invention may be practiced without these specific details. In other instances, well-known features, such as facility layouts or specific tool configurations, are not described in detail in order to not unnecessarily obscure embodiments of the present invention. Furthermore, it is to be understood that the various embodiments shown in the Figures are illustrative representations and are not necessarily drawn to scale. Additionally, other arrangements and configurations may not be explicitly disclosed in embodiments herein, but are still considered to be within the spirit and scope of the invention.

Disclosed herein are nano-spherical group III-nitride materials. In one embodiment, such a nano-spherical group III-nitride material is included in a light-emitting diode (LED) structure or in a laser diode (LD) structure.

Also disclosed herein are methods of forming nano-spherical group III-nitride materials by hydride vapor phase epitaxy. In one embodiment, a method includes using a nano-spherical group III-nitride material to form a light-emitting diode (LED) structure or in a laser diode (LD) structure.

Key concepts pertaining to various embodiments of the present invention may lead to the formation of nano-spherical group III-nitride materials or to the incorporation of such materials into LED or LD related devices. Such concepts may include: (a) hydride or halide vapor phase epitaxy (HYPE), (b) the formation of gallium nitride or other group III nitrides, (c) dimensions on the micro- or nano-scale, (d) light-emitting diodes (LEDs), and (e) laser diodes (LDs). The materials and/or processes described herein may also pertain to electronic devices such as field emission transistors.

In accordance with an embodiment of the present invention, methods of producing nano-structural group III-nitrides on different substrates are disclosed. In an embodiment, the nano-structural group III-nitrides are or are essentially nano-spherical. The nano-spherical group III-nitrides structures are composed of nano-scale hexagonal-shaped rods. For example, in one embodiment, the rods have a diameter approximately in the range of 50 nanometers-100 nanometers and a length approximately in the range of 200 nanometers-500 nanometers are packed in a way to provide the nano-speherical structure. However, it is noted that the specific ranges provided for the hexagonal-shaped rods are merely an embodiment and that the nano-spherical group III-nitride materials described herein are not necessarily limited to those dimensions.

In accordance with an embodiment of the present invention, an LED or LD device is formed based on a nano-spherical group III-nitride material or the nano-spherical group III-nitride material is used as a high purity source of material for fabricating such devices. In the former case, in an exemplary embodiment, each of a plurality of nanorod group III-nitrides structures is composed of an n-type gallium nitride (n-GaN)/indium gallium nitride (InGaN)/multi-layer quantum well layers (MQWs)/aluminum gallium nitride (AlGaN)/p-type gallium nitride (p-GaN) core-shell structure. In an embodiment, each nano-sperical structure is a core-shell structure and, in particular embodiment, each nano-spherical structure is arranged to have a different composition. A group of such differing nano-spherical structures may be combined on a single substrate to cover a band-gap spectrum approximately in the range of 0.7 eV to 6.2 eV.

One-dimensional structures composed of GaN or other group III-nitride materials (e.g., binary and ternary alloys in an In—Al—Ga—N system) may provide unique material properties such as, but not limited to, a direct wide band gap approximately in the range of 0.7 eV to 6.2 eV, a high breakdown electric field, and high saturated velocities. In an embodiment, high saturated velocities may have great potential for novel device application, including for LEDs, LDs, and other related electronic devices. In accordance with an embodiment of the present invention, a controlled synthesis and reproducable assembling of nano-structured group III-nitride materials is the key to achieve and demonstrate efficient devices.

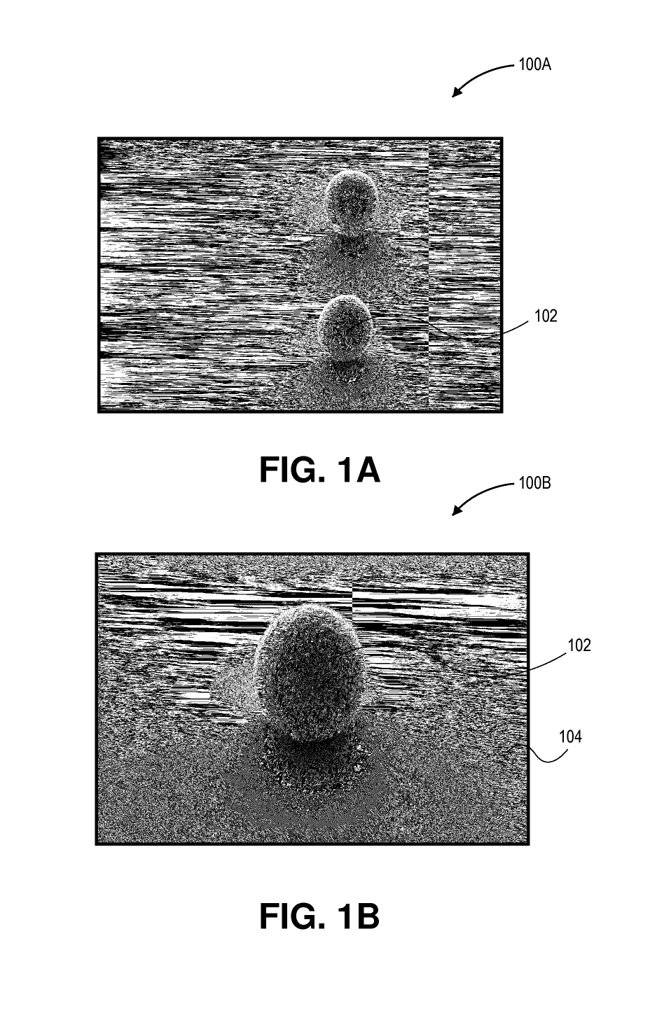

A nano-spherical group III-nitride material structure may be fabricated by HVPE for light-emmiting and laser device applications. FIG. 1A is a scanning electron microscope image 100A of an angled top-down view of a pair of nano-spherical group III-nitride material structures, in accordance with an embodiment of the present invention. FIG. 1B is a scanning electron microscope image blown-up view 100B of one of the pair of nano-spherical group III-nitride material structures from FIG. 1A, in accordance with an embodiment of the present invention.

Referring to FIGS. 1A and 1B, a nano-spherical gallium nitride (GaN) structure 102 is formed on a substrate 104 using an Applied Materials™ HVPE system. It is noted that almost all conventional growth techniques for one-dimensional materials involve using a catalyst or template-assisted growth. However, in accordance with an embodiment of the present invention, nano-spherical gallium nitride structure 102 was formed without the use of a catalyst or template-assisted growth. Instead, nano-spherical gallium nitride structure 102 is grown by a non-catalitic, template-free HVPE technique. In a very specific embodiment, nano-spherical gallium nitride structure 102 is formed by HVPE with the following conditions: a growth temperature approximately in the range of 500-1100 degrees Celcius, a growth pressure approximately in the range of 100 Torr-760 Torr, a Cl/Ga/Al/In inlet ratio of 0-6, an additional Cl₂ flow approximately in the range of 0-1000 sccm, a N/Ga, Al/In ratio approximately in the range of 10-10000. In a particular embodiment, Cl₂ is flowed above a metal source and the ratio parameters are the most important parameters to achieve a GaN structure having a nano-spherical growth mode. It is to be understood that the above growth conditions are exemplary and should not limit the scope and spirit of other embodiments of the present invention. In an embodiment, nano-spherical gallium nitride structure 102 is grown to have a diameter approximately in the range of 10-12 microns.

With respect to substrate 104, in an embodiment, a sapphire substrate is used. However, a similar approach may be used even in the presence of a non-sapphire substrate. Such other substrates may include, but are not limited to a silicon substrate, a silicon carbide substrate, a lithium aluminum oxide substrate, a lithium gallium oxide substrate, a zinc oxide substrate, a magnesium oxide substrate, a scandium magnesium oxide substrate, or a glass substrate. In an embodiment, a film of the majority composition of nano-spherical gallium nitride structure 102, e.g. a gallium nitride film, is formed on the surface of substrate 104 during formation of nano-spherical gallium nitride structure 102. The film ultimately is sandwiched by nano-spherical gallium nitride (GaN) structure 102 and substrate 104, as is depicted in FIG. 1A.

In accordance with an embodiment of the present invention, nano-spherical group III-nitride material structures, such as the structures described in association with FIGS. 1A and 1B, are composed nanoscale hexagonal-shaped rods. In one embodiment, the nano-shaped rods have a diameter approximately in the range of 50-100 nanometers and a length approximately in the range of 200-500 nanometers. In a specific embodiment, the shape of the nano-rods is exclusively hexagonal-phase. In a particular embodiment, the hexagonal-phase nanorods are composed entirely of or essentially of gallium nitride.

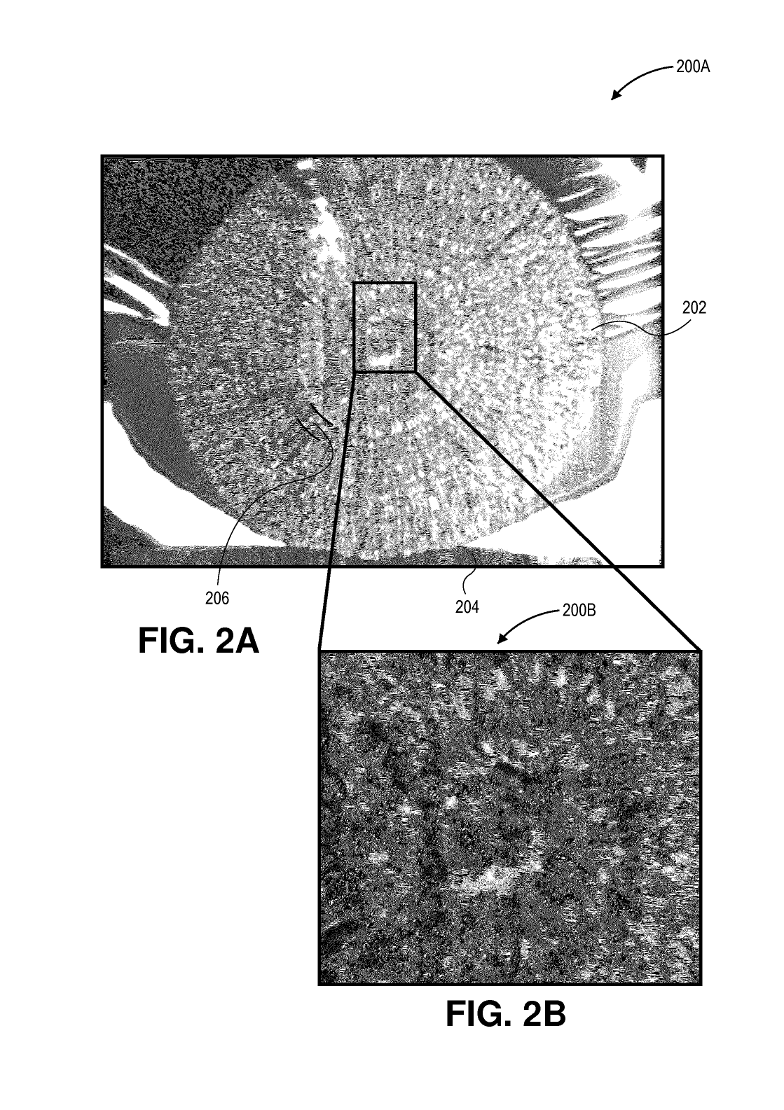

FIG. 2A is a cross-sectional tunneling electron microscope (TEM) image 200A of a nano-spherical group III-nitride material structure, in accordance with an embodiment of the present invention. FIG. 2B is tunneling electron microscope (TEM) image blown-up view 200B of the nano-spherical group III-nitride material structure from FIG. 2A, in accordance with an embodiment of the present invention.

Referring to FIGS. 2A and 2B, a nano-spherical gallium nitride (GaN) structure 202 is disposed on a substrate 204. Nano-spherical gallium nitride structure 202 is composed of a plurality of nano-rods loosely packed in concentric rings 206 of varying densities. In an embodiment, the nano-rods originate from a center point of the nano-spherical gallium nitride structure 202 and are aligned radially outwards, as depicted in FIGS. 2A and 2B.

With respect to substrate 204, in an embodiment, a sapphire substrate is used. However, a similar approach may be used even in the presence of a non-sapphire substrate. Such other substrates may include, but are not limited to a silicon substrate, a silicon carbide substrate, a lithium aluminum oxide substrate, a lithium gallium oxide substrate, a zinc oxide substrate, a magnesium oxide substrate, a scandium magnesium oxide substrate, or a glass substrate. In an embodiment, a film of the majority composition of nano-spherical gallium nitride structure 202, e.g. a gallium nitride film, is formed on the surface of substrate 104 during formation of nano-spherical gallium nitride structure 202. The film ultimately is sandwiched by nano-spherical gallium nitride (GaN) structure 202 and substrate 204, as is depicted in FIG. 2A.

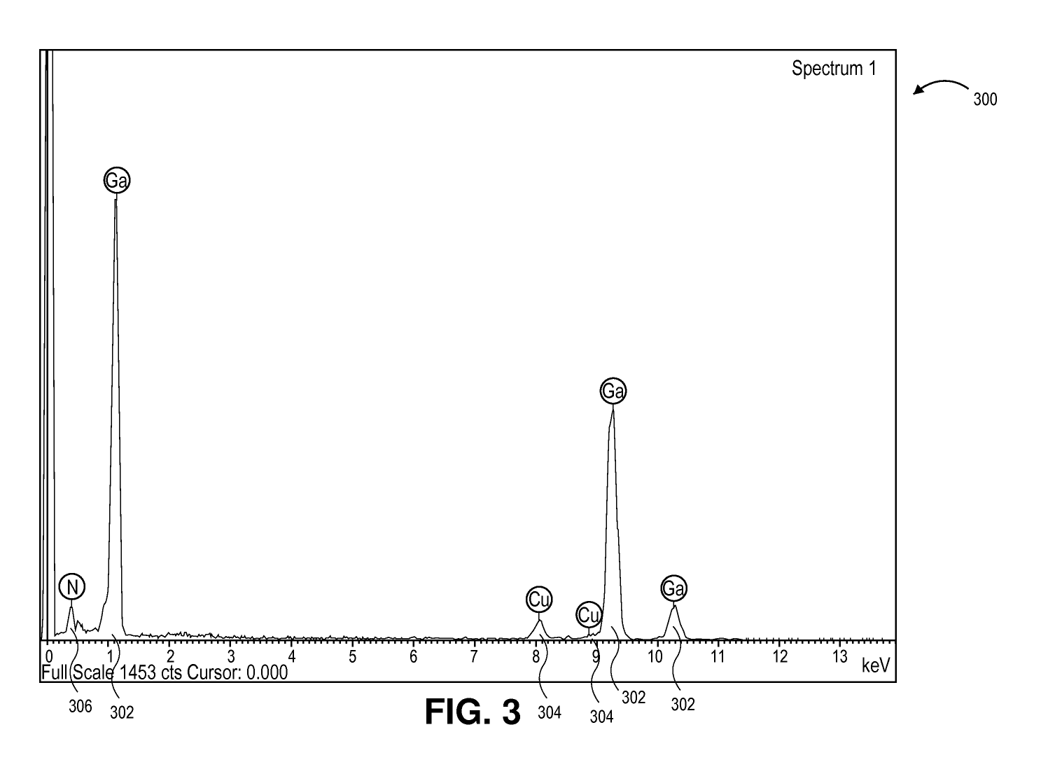

With respect to the chemical composition of nano-spherical gallium nitride structure 202, in an embodiment, nano-spherical gallium nitride structure 202 is composed entirely of or essentially entirely of gallium and nitrogen. The composition is the same composition as the gallium nitride film grown on the top surface of substrate 204 during growth of nano-spherical gallium nitride structure 202. FIG. 3 illustrates a compositional plot of the atomic composition of a nano-spherical group III-nitride material structure, in accordance with an embodiment of the present invention.

Referring to FIG. 3, an EDS tunneling electron microscope spectrum 300 indicates that a gallium nitride nano-spherical structured material grown at a temperature greater than approximately 965 degrees Celcius includes gallium 302 and nitrogen 306. There are no chlorine, oxygen, or carbon impurities and only a negligible amount of copper 304 in the baseline. As such, in accordance with an embodiment of the present invention, a nano-spherical group III-nitride material, such as nano-spherical gallium nitride (GaN) structure 202, may be a hight purity source of a group III-V material such as gallium nitride.

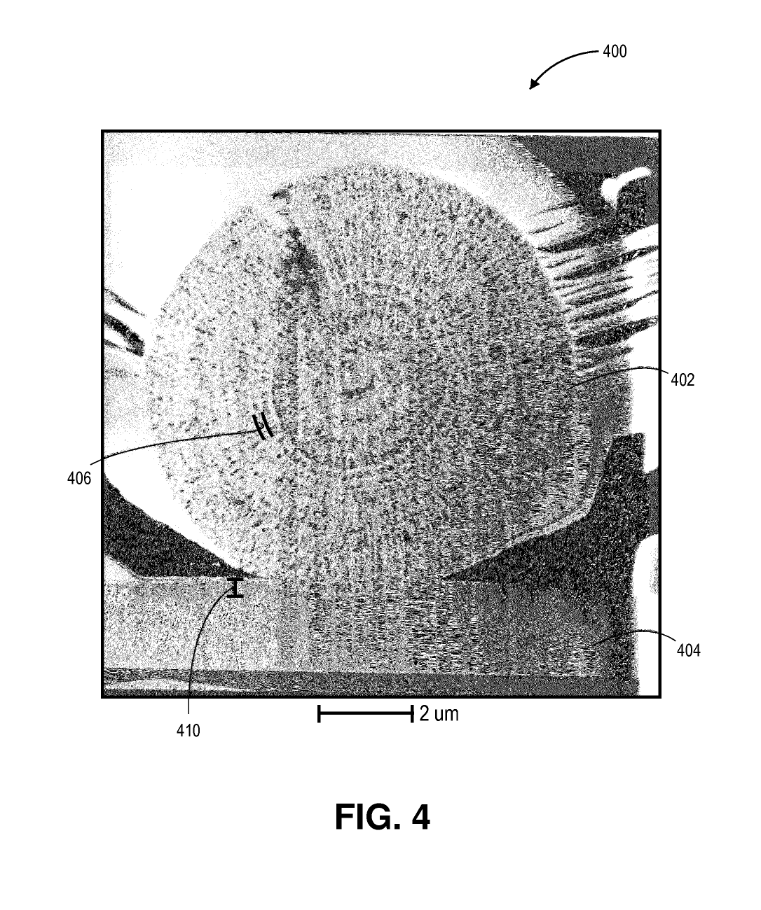

In an embodiment, as determined by the morphology of nano-spherical gallium nitride structure 202 and its association with a gallium nitride film formed between substrate 204 and nano-spherical gallium nitride structure 202, nano-spherical gallium nitride structure 202 is not nucleated on the gallium nitride film surface surface, but rather is grown to its full size inside of an HVPE chamber (e.g., in the gas phase) and eventually “dropped off” onto the gallium nitride film sometime prior to completion of the growth. FIG. 4 is a high angle annular dark field TEM image of a cross-sectional view of a nano-spherical group III-nitride material structure, in accordance with an embodiment of the present invention.

Referring to FIG. 4, a nano-spherical gallium nitride (GaN) structure 402 is disposed above a substrate which has a gallium nitride layer 404 formed thereon. In an embodiment, gallium nitride layer 404 is formed on the surface of the substrate during formation of nano-spherical gallium nitride structure 402. As such, gallium nitride layer 404 ultimately is sandwiched by nano-spherical gallium nitride structure 402 and the substrate, as is depicted in FIG. 4. In one embodiment, nano-spherical gallium nitride structure 402 falls onto the surface of gallium nitride layer 404 prior to completion of the growth of gallium nitride layer 404. As such, nano-spherical gallium nitride structure 402 appears embedded in gallium nitride layer 404 by an amount 410. In a specific embodiment, nano-spherical gallium nitride structure 402 is embedded into gallium nitride layer 404 at a depth approximately up to a range of 270-290 nanometers. In an embodiment, the continued growth of gallium nitride layer 404 occurs around the base of the nano-spherical gallium nitride structure 402, but not on nano-spherical gallium nitride structure 402 itself, as is depicted in FIG. 4. In an embodiment, nano-spherical gallium nitride structure 402 is composed of a plurality of nano-rods loosely packed in concentric rings 406, as is also depicted in FIG. 4.

It is to be understood that varying structural or compostional nanosperical units may be fabricated. For example, in accordance with an embodiment of the present invention, with each concentric ring viwed as a core shell structure, a plurality of concentric rings assembled into a spherical shape, with at least two adjacent concentric rings composed of different material combinations to provide a different band-gap materials adjacent one another. In an embodiment, a device based on nano-spherical structures with differing concentric rings of material is used to provide a nGaN/InGaN MQWs/AlGaN/pGaN arrangement with each concentric ring forming one of the layers in the stack. In another embodiment, the incorporation of certain III-V elements, such as indium, is greater in a nano-sphere than in a one-dimensional material. This result may enable the opportunity to fabricate devices that cover the whole visible spectrum and crete a full color display from a single nanospherical particle. In a similar approach, laser diodes may be fabricated to have a tunable wavelength.

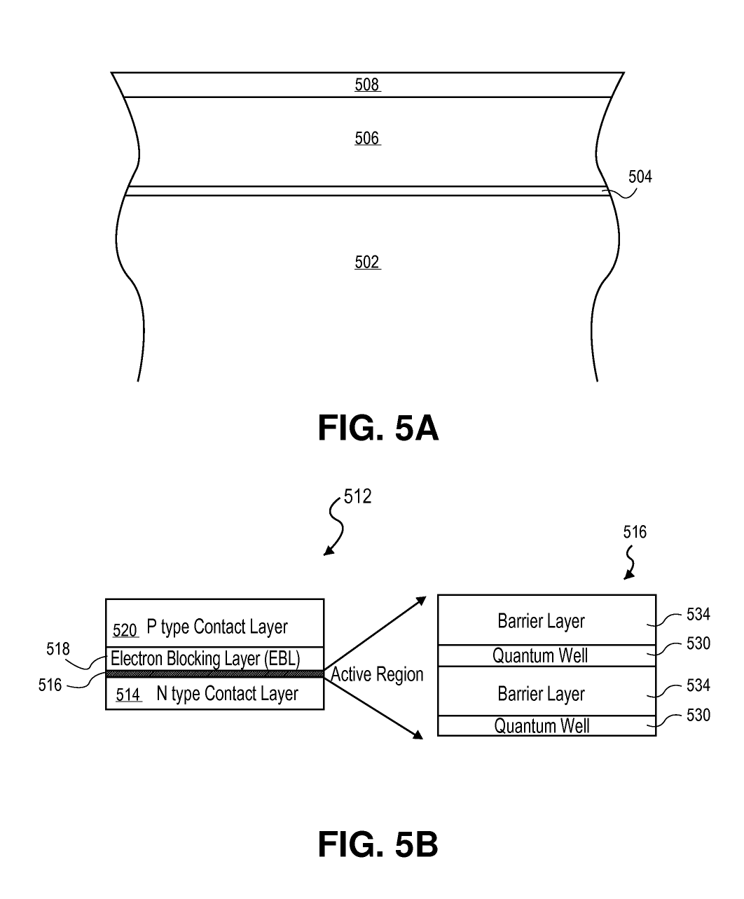

A nano-spherical group III-nitride material structure may be used as a base or backbone in the fabrication of a light-emitting diode (LED) device. Alternatively, nano-spherical group III-nitride material structure may serves as a source of high quality material that may be isolated and incorporated into a light-emitting diode (LED) device or other III-V material device. For example, FIGS. 5A and 5B illustrate cross-sections of a representative LED device, in accordance with an embodiment of the present invention.

Referring to FIG. 5A, a gallium nitride (GaN) single crystalline film 506 is epitaxially grown or is disposed on a substrate 502. An optional buffer layer 504, such as an aluminum nitride (AlN) layer, a gallium nitride (GaN) layer, or related ternary aluminum gallium nitride (AlGaN) or indium gallium nitride (InGaN) alloy layers, may be formed between the gallium nitride (GaN) film 506 and the substrate 502. Substrate 502 may be any suitable single crystalline substrate upon which a gallium nitride (GaN) single crystalline film 506 may be formed. Substrate 502 may be any suitable substrate, such as but not limited to a sapphire (Al₂O₃) substrate, a silicon carbide (SiC) substrate, a silicon on diamond (SOD) substrate, a quartz (SiO₂) substrate, a glass substrate, a zinc oxide (ZnO) substrate, a magnesium oxide (MgO) substrate and a lithium aluminum oxide (LiAlO₂) substrate. In a specific embodiment, substrate 502 is a (0001) sapphire substrate. Sapphire substrates are ideal for use in manufacturing of LEDs because they increase light extraction efficiency which is extremely useful in the fabrication of a new generation of solid state lighting devices.

Gallium nitride (GaN) film 506 may be a gallium nitride (GaN) film containing only gallium nitride (GaN) or may be a gallium nitride (GaN) alloy film, such as for an example aluminum gallium nitride (AlGaN). In an embodiment of the present invention, the aluminum gallium nitride film has a composition of AlₓGa₁₋ₓN (0≦x≦1). The gallium nitride film or alloy film can have a thickness between 2-500 microns is typically formed between 2-15 microns. In an embodiment of the present invention, the gallium nitride film has a thickness of at least 3 microns to sufficiently suppress threading dislocations. In an embodiment, the source of gallium nitride in film 506 is a nano-spherical group III-nitride material.

Referring to FIG. 5B, LED device layers 508 (depicted as a single layer in FIG. 5A) may include an n type contact layer 514, an active region 516, an electron blocking layer 518, and a p type contact layer 520. The active region 516 may comprise a plurality of active layers including a single or multiple quantum wells 530, such as indium gallium nitride (InGaN), formed on a single or multiple barrier layers 534, such as gallium nitride (GaN). In an embodiment, one of the layers depicted in FIG. 5B is formed from a nano-spherical group III-nitride material, the nano-spherical group III-nitride material formed by an HVPE process.

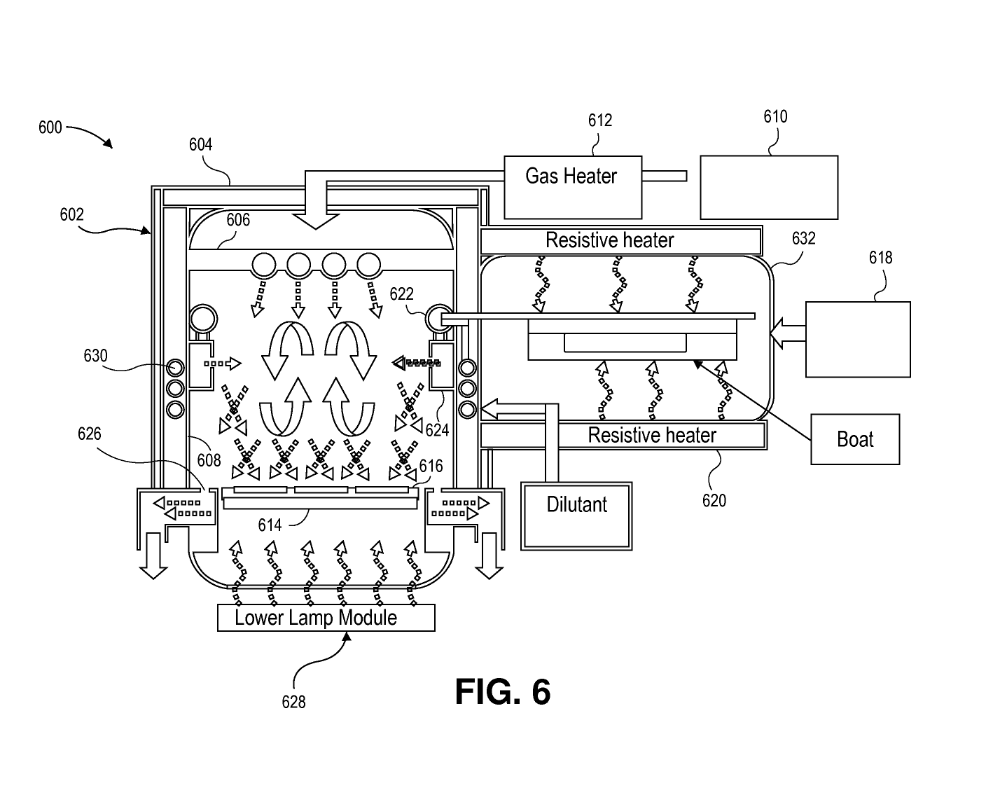

An example of a HVPE deposition chamber which may be utilized to deposit nano-spherical group III-nitride material structures or similar structures in accordance with embodiments of the present invention is illustrated and described with respect to FIG. 6.

FIG. 6 is a schematic view of an HVPE apparatus 600 according to one embodiment. The apparatus includes a chamber 602 enclosed by a lid 604. Processing gas from a first gas source 610 is delivered to the chamber 602 through a gas distribution showerhead 606. In one embodiment, the gas source 610 may comprise a nitrogen containing compound. In another embodiment, the gas source 610 may comprise ammonia. In one embodiment, an inert gas such as helium or diatomic nitrogen may be introduced as well either through the gas distribution showerhead 606 or through the walls 608 of the chamber 602. An energy source 612 may be disposed between the gas source 610 and the gas distribution showerhead 606. In one embodiment, the energy source 612 may comprise a heater. The energy source 612 may break up the gas from the gas source 610, such as ammonia, so that the nitrogen from the nitrogen containing gas is more reactive.

To react with the gas from the first source 610, precursor material may be delivered from one or more second sources 618. The one or more second sources 618 may comprise precursors suitable for forming nano-spherical group III-nitride material structures. The precursor may be delivered to the chamber 602 by flowing a reactive gas over and/or through the precursor in the precursor source 618. In one embodiment, the reactive gas may comprise a chlorine containing gas such as diatomic chlorine. The chlorine containing gas may react with the precursor source to form a chloride. In order to increase the effectiveness of the chlorine containing gas to react with the precursor, the chlorine containing gas may snake through the boat area in the chamber 632 and be heated with the resistive heater 620. By increasing the residence time that the chlorine containing gas is snaked through the chamber 632, the temperature of the chlorine containing gas may be controlled. By increasing the temperature of the chlorine containing gas, the chlorine may react with the precursor faster. In other words, the temperature is a catalyst to the reaction between the chlorine and the precursor mixture.

In order to increase the reactiveness of the precursor, the precursor may be heated by a resistive heater 620 within the second chamber 632 in a boat. The chloride reaction product may then be delivered to the chamber 602. The reactive chloride product first enters a tube 622 where it evenly distributes within the tube 622. The tube 622 is connected to another tube 624. The chloride reaction product enters the second tube 624 after it has been evenly distributed within the first tube 622. The chloride reaction product then enters into the chamber 602 where it mixes with the nitrogen containing gas to form a nitride layer or nano-structure on the substrate 616 that is disposed on a susceptor 614. In one embodiment, the susceptor 614 may comprise silicon carbide. The nitride layer or nano-structure may comprise gallium nitride or aluminum nitride for example. The other reaction products, such as nitrogen and chlorine, are exhausted through an exhaust 626.

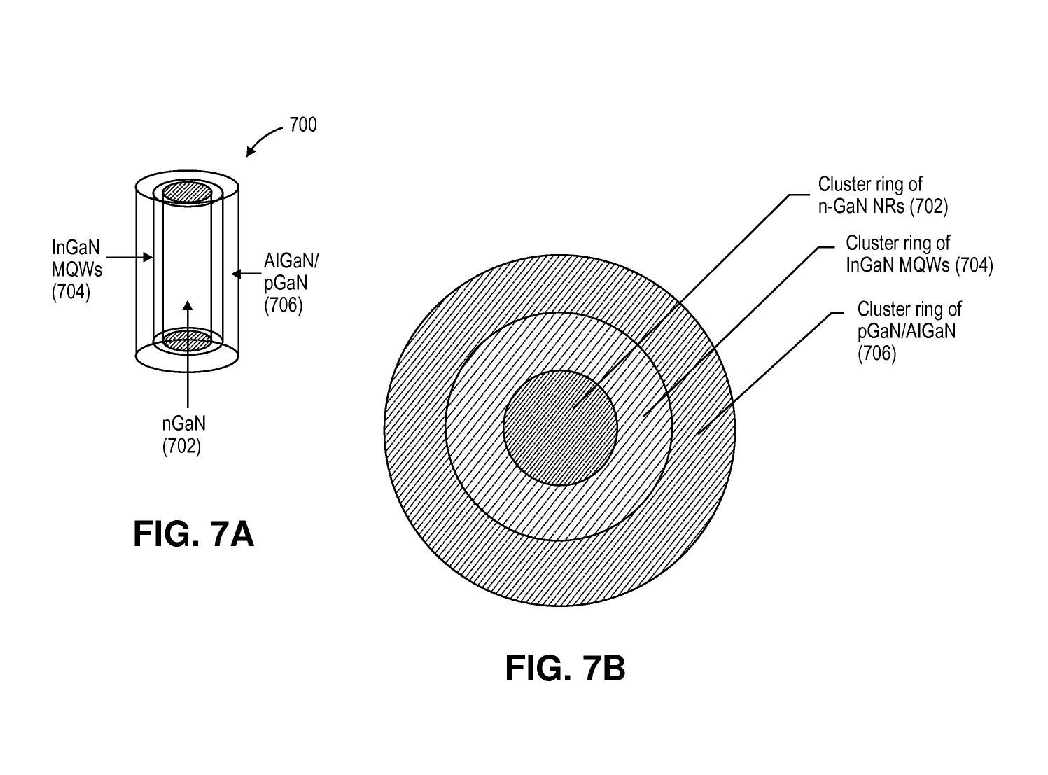

In another aspect of the present invention, instead of being a source of material for a conventional LED or similar device, as described above in association with FIGS. 5A and 5B, a nano-spherical group III-nitride material may be used to fabricate a 1-dimensional LED or similar device. For example, FIG. 7A illustrates a transparent, isometric view of a representative portion of an LED device, in accordance with an embodiment of the present invention. FIG. 7B illustrates a top-down view of a representative portion of an LED device, in accordance with an embodiment of the present invention.

Referring to FIG. 7A, a 1-dimensional LED or similar device 700 includes an N-type gallium nitride core 702 surrounded by a stack of multiple indium gallium nitride quantum wells 704 as a cluster shell, which in turn is surrounded by an aluminum gallium nitride shell blocking layer/P-type gallium nitride shell 706. In accordance with an embodiment of the present invention, each gallium nitride nano-rod of a nano-spherical group III-nitride material structure is used as a foundation to form a single device, a singe one of such devices depicted in FIG. 7A. Referring to 7B, a top-down view of 1-dimensional LED or similar device 700 includes N-type gallium nitride core 702 surrounded by stack of multiple indium gallium nitride quantum wells 704 as a cluster shell, which in turn is surrounded by aluminum gallium nitride shell blocking layer/P-type gallium nitride shell 706.

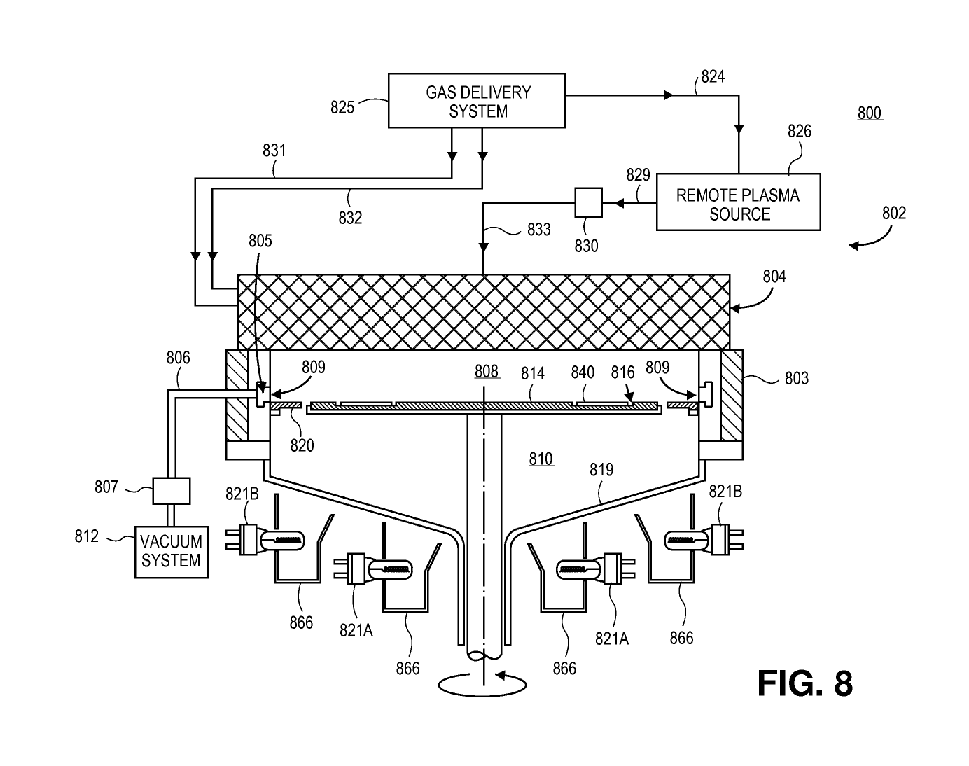

Embodiments of the present invention may also include formation of nano-spherical group III-nitride materials or related films by metal-organic chemical vapor deposition (MOCVD). An example of an MOCVD deposition chamber which may be utilized to deposit nano-spherical group III-nitride materials or related films, in accordance with embodiments of the present invention, is illustrated and described with respect to FIG. 8.

FIG. 8 is a schematic cross-sectional view of an MOCVD chamber according to an embodiment of the invention. Exemplary systems and chambers that may be adapted to practice the present invention are described in U.S. patent application Ser. No. 11/404,516, filed on Apr. 14, 2006, and Ser. No. 11/429,022, filed on May 5, 2006, both of which are incorporated by reference in their entireties.

The apparatus 800 shown in FIG. 8 includes a chamber 802, a gas delivery system 825, a remote plasma source 826, and a vacuum system 812. The chamber 802 includes a chamber body 803 that encloses a processing volume 808. A showerhead assembly 804 is disposed at one end of the processing volume 808, and a substrate carrier 814 is disposed at the other end of the processing volume 808. A lower dome 819 is disposed at one end of a lower volume 810, and the substrate carrier 814 is disposed at the other end of the lower volume 810. The substrate carrier 814 is shown in process position, but may be moved to a lower position where, for example, the substrates 840 may be loaded or unloaded. An exhaust ring 820 may be disposed around the periphery of the substrate carrier 814 to help prevent deposition from occurring in the lower volume 810 and also help direct exhaust gases from the chamber 802 to exhaust ports 809. The lower dome 819 may be made of transparent material, such as high-purity quartz, to allow light to pass through for radiant heating of the substrates 840. The radiant heating may be provided by a plurality of inner lamps 821A and outer lamps 821B disposed below the lower dome 819, and reflectors 866 may be used to help control chamber 802 exposure to the radiant energy provided by inner and outer lamps 821A, 821B. Additional rings of lamps may also be used for finer temperature control of the substrate 840.

The substrate carrier 814 may include one or more recesses 816 within which one or more substrates 840 may be disposed during processing. The substrate carrier 814 may carry six or more substrates 840. In one embodiment, the substrate carrier 814 carries eight substrates 840. It is to be understood that more or less substrates 840 may be carried on the substrate carrier 814. Typical substrates 840 may include sapphire, silicon carbide (SiC), silicon, or gallium nitride (GaN). It is to be understood that other types of substrates 840, such as glass substrates 840, may be processed. Substrate 840 size may range from 50 mm-100 mm in diameter or larger. The substrate carrier 814 size may range from 200 mm-750 mm. The substrate carrier 814 may be formed from a variety of materials, including SiC or SiC-coated graphite. It is to be understood that substrates 840 of other sizes may be processed within the chamber 802 and according to the processes described herein. The showerhead assembly 804 may allow for more uniform deposition across a greater number of substrates 840 and/or larger substrates 840 than in traditional MOCVD chambers, thereby increasing throughput and reducing processing cost per substrate 840.

The substrate carrier 814 may rotate about an axis during processing. In one embodiment, the substrate carrier 814 may be rotated at about 2 RPM to about 100 RPM. In another embodiment, the substrate carrier 814 may be rotated at about 30 RPM. Rotating the substrate carrier 814 aids in providing uniform heating of the substrates 840 and uniform exposure of the processing gases to each substrate 840.

The plurality of inner and outer lamps 821A, 821B may be arranged in concentric circles or zones (not shown), and each lamp zone may be separately powered. In one embodiment, one or more temperature sensors, such as pyrometers (not shown), may be disposed within the showerhead assembly 804 to measure substrate 840 and substrate carrier 814 temperatures, and the temperature data may be sent to a controller (not shown) which can adjust power to separate lamp zones to maintain a predetermined temperature profile across the substrate carrier 814. In another embodiment, the power to separate lamp zones may be adjusted to compensate for precursor flow or precursor concentration non-uniformity. For example, if the precursor concentration is lower in a substrate carrier 814 region near an outer lamp zone, the power to the outer lamp zone may be adjusted to help compensate for the precursor depletion in this region.

The inner and outer lamps 821A, 821B may heat the substrates 840 to a temperature of about 400 degrees Celsius to about 1200 degrees Celsius. It is to be understood that the invention is not restricted to the use of arrays of inner and outer lamps 821A, 821B. Any suitable heating source may be utilized to ensure that the proper temperature is adequately applied to the chamber 802 and substrates 840 therein. For example, in another embodiment, the heating source may comprise resistive heating elements (not shown) which are in thermal contact with the substrate carrier 814.

A gas delivery system 825 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 802. Different gases, such as precursor gases, carrier gases, purge gases, cleaning/etching gases or others may be supplied from the gas delivery system 825 to separate supply lines 831, 832, and 833 to the showerhead assembly 804. The supply lines 831, 832, and 833 may include shut-off valves and mass flow controllers or other types of controllers to monitor and regulate or shut off the flow of gas in each line.

A conduit 829 may receive cleaning/etching gases from a remote plasma source 826. The remote plasma source 826 may receive gases from the gas delivery system 825 via supply line 824, and a valve 830 may be disposed between the showerhead assembly 804 and remote plasma source 826. The valve 830 may be opened to allow a cleaning and/or etching gas or plasma to flow into the showerhead assembly 804 via supply line 833 which may be adapted to function as a conduit for a plasma. In another embodiment, apparatus 800 may not include remote plasma source 826 and cleaning/etching gases may be delivered from gas delivery system 825 for non-plasma cleaning and/or etching using alternate supply line configurations to shower head assembly 804.

The remote plasma source 826 may be a radio frequency or microwave plasma source adapted for chamber 802 cleaning and/or substrate 840 etching. Cleaning and/or etching gas may be supplied to the remote plasma source 826 via supply line 824 to produce plasma species which may be sent via conduit 829 and supply line 833 for dispersion through showerhead assembly 804 into chamber 802. Gases for a cleaning application may include fluorine, chlorine or other reactive elements.

In another embodiment, the gas delivery system 825 and remote plasma source 826 may be suitably adapted so that precursor gases may be supplied to the remote plasma source 826 to produce plasma species which may be sent through showerhead assembly 804 to deposit CVD layers, such as films, for example, on substrates 840.

A purge gas (e.g., nitrogen) may be delivered into the chamber 802 from the showerhead assembly 804 and/or from inlet ports or tubes (not shown) disposed below the substrate carrier 814 and near the bottom of the chamber body 803. The purge gas enters the lower volume 810 of the chamber 802 and flows upwards past the substrate carrier 814 and exhaust ring 820 and into multiple exhaust ports 809 which are disposed around an annular exhaust channel 805. An exhaust conduit 806 connects the annular exhaust channel 805 to a vacuum system 812 which includes a vacuum pump (not shown). The chamber 802 pressure may be controlled using a valve system 807 which controls the rate at which the exhaust gases are drawn from the annular exhaust channel 805.

It is to be understood that embodiments of the present invention may include the use of substrates, such as but not limited to a sapphire (Al₂O₃) substrate, a silicon carbide (SiC) substrate, a silicon on diamond (SOD) substrate, a quartz (SiO₂) substrate, a glass substrate, a zinc oxide (ZnO) substrate, a magnesium oxide (MgO) substrate, and a lithium aluminum oxide (LiAlO₂) substrate. Any well know method, such as masking and etching may be utilized to form features, such as posts, from a planar substrate to create a patterned substrate. In a specific embodiment, however, the patterned substrate is a (0001) patterned sapphire substrate (PSS). Patterned sapphire substrates may be ideal for use in the manufacturing of LEDs because they increase the light extraction efficiency which is extremely useful in the fabrication of a new generation of solid state lighting devices. Other embodiments include the use of planar (non-patterned) substrates, such as a planar sapphire substrate.

In some embodiments, growth of a gallium nitride or related material on a substrate is performed along a (0001) Ga-polarity, N-polarity, or non-polar a-plane {112-0} or m-plane 1101-01, or semi-polar planes. In some embodiments, posts formed in a patterned growth substrate are round, triangular, hexagonal, rhombus shape, or other shapes effective for block-style growth. In an embodiment, the patterned substrate contains a plurality of features (e.g., posts) having a cone shape. In a particular embodiment, the feature has a conical portion and a base portion. In an embodiment of the present invention, the feature has a tip portion with a sharp point to prevent over growth. In an embodiment, the tip has an angle (θ) of less than 145° and ideally less than 110°. Additionally, in an embodiment, the feature has a base portion which forms a substantially 90° angle with respect to the xy plane of the substrate. In an embodiment of the present invention, the feature has a height greater than one micron and ideally greater than 1.5 microns. In an embodiment, the feature has a diameter of approximately 3.0 microns. In an embodiment, the feature has a diameter height ratio of approximately less than 3 and ideally less than 2. In an embodiment, the features (e.g., posts) within a discrete block of features (e.g., within a block of posts) are spaced apart by a spacing of less than 1 micron and typically between 0.7 to 0.8 microns.

It is also to be understood that embodiments may include a Group III-Nitride epitaxial film that can be suitably deposited by hydride vapor phase epitaxy or MOCVD, or the like, deposition. The Group III-Nitride film may be a binary, ternary, or quaternary compound semiconductor film formed from a group III element or elements selected from gallium, indium and aluminum and nitrogen. That is, the Group III-Nitride crystalline film can be any solid solution or alloy of one or more Group III element and nitrogen, such as but not limited to GaN, AlN, InN, AlGaN, InGaN, InAlN, and InGaAlN. However, in a specific embodiment, the Group III-Nitride film is an n-type gallium nitride (GaN) film. The Group III-Nitride film can have a thickness between 2-500 microns and is typically formed between 2-15 microns. Thicknesses greater than 500 microns are possible because of, e.g., the high growth rate of HYPE. In an embodiment of the present invention, the Group III-Nitride film has a thickness of at least 3.0 microns to sufficiently suppress threading dislocations. Additionally, as described above, the Group III-Nitride film can be doped. The Group III-Nitride film can be p-typed doped using any p-type dopant such as but not limited Mg, Be, Ca, Sr, or any Group I or Group II element have two valence electrons. The Group III-Nitride film can be p-type doped to a conductivity level of between 1×10¹⁶ to 1×10²⁰ atoms/cm³.

It is also to be understood that embodiments of the present invention need not be limited to the fabrication of LEDs. For example, in another embodiment, devices other than LED devices may be fabricated, such as but not limited to field-effect transistor (FET) devices. In such embodiments, there may not be a need for a p-type material on top of a structure of layers. Instead, an n-type or un-doped material may be used in place of the p-type layer.

Thus, nano-spherical group III-nitride materials and methods of forming nano-spherical group III-nitride materials have been disclosed. In accordance with an embodiment of the present invention, a nano-spherical group III-nitride material is included in a light-emitting diode structure or in a laser diode structure.

What is claimed is:

1. A Group III-V material structure, comprising:
a plurality of nano-scale rods arranged to form a nano-spherical or near-nano-spherical structure, each rod comprising a Group III-nitride material.

2. The Group III-V material structure of claim 1, wherein each nano-scale rod is a hexagonal-shaped rod.

3. The Group III-V material structure of claim 1, wherein each nano-scale rod has a diameter approximately in the range of 50-100 nanometers.

4. The Group III-V material structure of claim 1, wherein each nano-scale rod has a length approximately in the range of 200-500 nanometers.

5. The Group III-V material structure of claim 1, wherein the Group III-nitride material is gallium nitride.

6. The Group III-V material structure of claim 1, wherein the plurality of nano-scale rods is loosely packed in concentric rings of varying density.

7. The Group III-V material structure of claim 6, wherein the plurality of nano-scale rods originates from a center point of the nano-spherical or near-nano-spherical structure, and are aligned radially outwards.

8. The Group III-V material structure of claim 1, wherein the nano-spherical or near-nano-spherical structure has a diameter approximately in the range of 10-12 microns.

9. A method of forming a Group III-V material structure, the method comprising:
forming a layer of Group III-nitride material above a substrate; and
forming a plurality of nano-scale rods in a nano-spherical or near-nano-spherical arrangement, the arrangement formed on or in the layer of Group III-nitride material, and each rod comprising the Group III-nitride material.

10. The method of claim 9, wherein both the layer of Group III-nitride material and the plurality of nano-scale rods are formed in the same deposition process, the deposition process selected from the group consisting of an MOCVD deposition process and an HVPE deposition process.

11. The method of claim 10, wherein the deposition process is a non-catalytic, template-free HVPE deposition process.

12. The method of claim 11, wherein the non-catalytic, template-free HVPE deposition process is performed at a temperature approximately in the range of 500-1100 degrees Celsius and a pressure approximately in the range of 100 Torr-760 Torr.

13. The method of claim 9, wherein the plurality of nano-scale rods is not nucleated in or on the layer of Group III-nitride material, but is embedded into the layer of Group III-nitride material.

14. The method of claim 9, further comprising:
isolating an individual nano-scale rod from the plurality of nano-scale rods; and
forming a 1-dimensional LED device from the individual nano-scale rod.

15. The method of claim 9, wherein each nano-scale rod is a hexagonal-shaped rod.

16. The method of claim 9, wherein each nano-scale rod has a diameter approximately in the range of 50-100 nanometers, and wherein each nano-scale rod has a length approximately in the range of 200-500 nanometers.

17. The method of claim 9, wherein the Group III-nitride material is gallium nitride.

18. The method of claim 9, wherein the plurality of nano-scale rods is loosely packed in concentric rings of varying density.

19. The method of claim 18, wherein the plurality of nano-scale rods originates from a center point of the nano-spherical or near-nano-spherical structure, and are aligned radially outwards.

20. The method of claim 9, wherein the nano-spherical or near-nano-spherical structure has a diameter approximately in the range of 10-12 microns.
